(19) United States
(12) Patent Application Publication
(10) Pub. No.: US 2026/0107384 A1
(43) Pub. Date: Apr. 16, 2026

(54) CIRCUIT BOARD STRUCTURE

(71) Applicant: Unimicron Technology Corp., Taoyuan City (TW)

(72) Inventors: Guan-You Lin, Taipei City (TW); Ruey-Beei Wu, Taipei City (TW); Jun-Rui Huang, Tainan City (TW); Yi-Pin Lin, Taoyuan City (TW); Wei-Yu Liao, Taoyuan City (TW); Chi-Min Chang, Taoyuan City (TW); Ching Sheng Chen, Hsinchu County (TW)

(73) Assignee: Unimicron Technology Corp., Taoyuan City (TW)

(21) Appl. No.: 18/984,813

(22) Filed: Dec. 17, 2024

(30) Foreign Application Priority Data
Oct. 15, 2024 (TW) 113139088

(51) Int. Cl. H05K 1/11; H05K 1/02

(52) U.S. Cl. CPC H05K 1/115; H05K 1/0218; H05K 2201/09636

(57) ABSTRACT

A circuit board structure includes a substrate, a first coaxial conductive via, a second coaxial conductive via and ground vias. The substrate has a first surface and a second surface opposite to the first surface. The first coaxial conductive via and the second coaxial conductive via are disposed in the substrate. An impedance of the first coaxial conductive via and an impedance of the second coaxial conductive via are less than 50 ohms respectively. The ground vias surround the first coaxial conductive via and the second coaxial conductive via. The first coaxial conductive via and the second coaxial conductive via are configured to transfer a signal with a frequency in a range between 50 GHz and 68 GHz.

### CROSS-REFERENCE TO RELATED APPLICATION

This application claims the priority benefit of Taiwan application serial no. 113139088, filed on Oct. 15, 2024. The entirety of the above-mentioned patent application is hereby incorporated by reference herein and made a part of this specification.

### BACKGROUND

### Technical Field

The disclosure relates to a structure, and in particular relates to a circuit board structure.

### Description of Related Art

With the development of high-frequency communication applications, the design of circuit boards necessitates adaptation to meet impedance matching requirements and mitigate high-frequency losses. Furthermore, in light of the prevailing trend towards miniaturization and reduction in product dimensions, a pressing issue that warrants improvement is the augmentation of available space on circuit boards without compromising their electrical performance.

### SUMMARY

A circuit board structure that may increase the available space of the circuit board and has good electrical performance, is provided in the disclosure.

The circuit board structure of the disclosure includes a substrate, a first coaxial conductive via, a second coaxial conductive via, and multiple ground vias. The substrate has a first surface and a second surface opposite to the first surface. The first coaxial conductive via and the second coaxial conductive via are disposed in the substrate. An impedance of the first coaxial conductive via and an impedance of the second coaxial conductive via are less than 50 ohms respectively. The ground vias surround the first coaxial conductive via and the second coaxial conductive via. The first coaxial conductive via and the second coaxial conductive via are configured to transfer a signal with a frequency in a range between 50 GHz and 68 GHz.

In an embodiment of the disclosure, the substrate includes a core structure and a build-up structure. The build-up structure is disposed on the core structure, in which the build-up structure is close to the first surface of the substrate relative to the core structure.

In an embodiment of the disclosure, the first coaxial conductive via and the second coaxial conductive via each include a first conductive via, a second conductive via, and an insulating filling structure. The first conductive via penetrates the core structure. The second conductive via penetrates the core structure and the build-up structure, in which the first conductive via surrounds the second conductive via, and the first conductive via and the second conductive via have the same axis center. The insulating filling structure is located between the first conductive via and the second conductive via.

In an embodiment of the disclosure, a ratio of an inner diameter of the first conductive via to an outer diameter of the second conductive via is less than 4.

In an embodiment of the disclosure, the first conductive via is electrically connected to the ground vias.

In an embodiment of the disclosure, the ground vias penetrate the build-up structure and the core structure.

In an embodiment of the disclosure, a distance between an axis center of the first coaxial conductive via and an axis center of the second coaxial conductive via is less than 1.3 mm.

In an embodiment of the disclosure, the circuit board structure further includes a first top circuit layer, which is disposed on the build-up structure and is electrically connected to the second conductive via of the first coaxial conductive via.

In an embodiment of the disclosure, the first top circuit layer includes a pad portion, a first circuit portion, and a second circuit portion. The pad portion is disposed on the second conductive via of the first coaxial conductive via. The first circuit portion is disposed on the build-up structure. The second circuit portion is disposed on the build-up structure and connected between the pad portion and the first circuit portion, in which a width of the second circuit portion is less than a width of the first circuit portion.

In an embodiment of the disclosure, a shortest distance between centers of the ground vias and the axis center of the first coaxial conductive via is a first distance. A shortest distance between the centers of the ground vias and the axis center of the second coaxial conductive via is a second distance. A sum of the first distance and the second distance is greater than a distance between the axis center of the first coaxial conductive via and the axis center of the second coaxial conductive via.

Based on the above, the circuit board structure of the disclosure includes coaxial conductive vias. The coaxial conductive vias have low impedance and are configured to transfer a signal with a frequency in a range between 50 GHz and 68 GHZ, thereby increasing the space utilization of the circuit board, while taking into account the integrity of the transferred signal.

### BRIEF DESCRIPTION OF THE DRAWINGS

FIG. 1 is a top view schematic diagram of a circuit board structure according to an embodiment of the disclosure.

FIG. 2 is a sectional schematic diagram of a circuit board structure according to an embodiment of the disclosure.

FIG. 3 is a cross-sectional schematic diagram of a coaxial conductive via according to an embodiment of the disclosure.

FIG. 4 is a graph showing the relationship between the reflection loss parameter S11 of the coaxial conductive via and the frequency.

### DETAILED DESCRIPTION OF DISCLOSED EMBODIMENTS

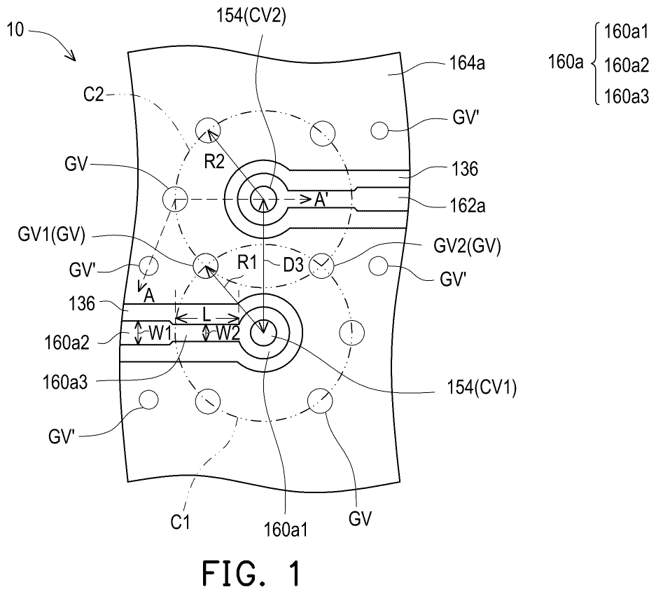

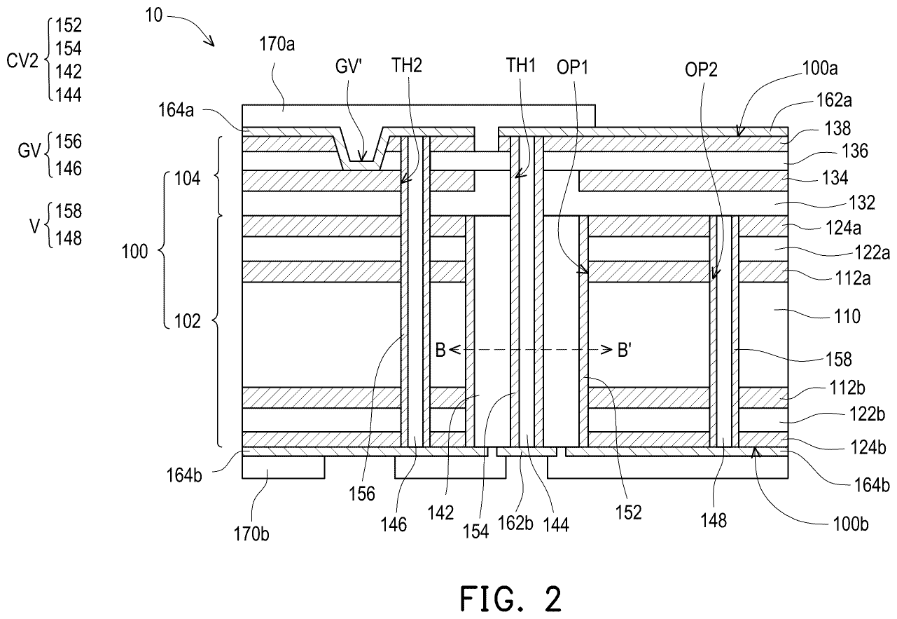

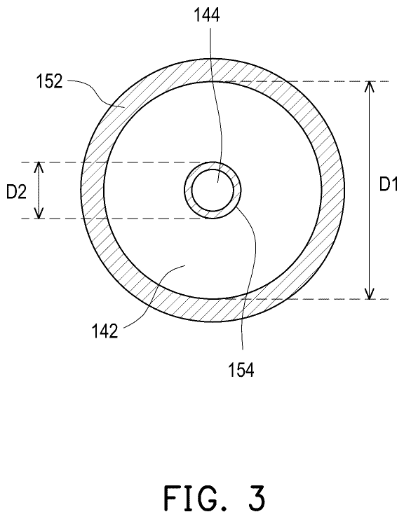

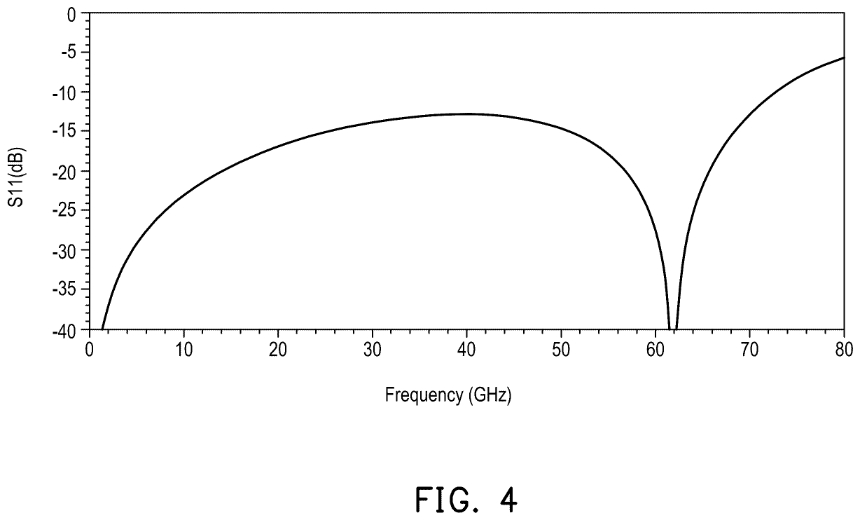

FIG. 1 is a top view schematic diagram of a circuit board structure according to an embodiment of the disclosure. FIG. 2 is a sectional schematic diagram of a circuit board structure according to an embodiment of the disclosure. FIG. 3 is a cross-sectional schematic diagram of a coaxial conductive via according to an embodiment of the disclosure. FIG. 4 is a graph showing the relationship between the reflection loss parameter S11 of the coaxial conductive via and the frequency. FIG. 2 may be a sectional schematic diagram cut along line A-A′ of FIG. 1. FIG. 3 may be a cross-sectional schematic diagram cut along line B-B′ of FIG. 2. For clarity of illustration, FIG. 1 only shows the first top circuit layer 160a, the second top circuit layer 162a, the third top circuit layer 164a, the second insulating layer 136, the second conductive via 154 of the first coaxial conductive via CV1 and the second coaxial conductive via CV2, and the ground via GV, other omitted parts may be understood with reference to FIG. 2. In addition, it should be understood that the sectional schematic diagram of the first coaxial conductive via CV1 is similar to the sectional schematic diagram (as shown in FIG. 2) of the second coaxial conductive via CV2.

Referring to FIG. 1 to FIG. 3, the circuit board structure 10 includes a substrate 100, the first coaxial conductive via CV1 and the second coaxial conductive via CV2, and multiple ground vias GV. The substrate 100 has a first surface 100a and a second surface 100b opposite to the first surface 100a. The first coaxial conductive via CV1 and the second coaxial conductive via CV2 are disposed in the substrate 100. The ground vias GV surround the first coaxial conductive via CV1 and the second coaxial conductive via CV2.

In some embodiments, the substrate 100 includes a core structure 102 and a build-up structure 104. The build-up structure 104 is disposed on the core structure 102, in which the build-up structure 104 is close to the first surface 100a of the substrate 100 relative to the core structure 102, and the core structure 102 is close to the second surface 100b of the substrate 100 relative to the build-up structure 104.

The core structure 102 may include a core layer 110, a core conductive layer 112a, a core conductive layer 112b, an insulating layer 122a, an insulating layer 122b, a conductive layer 124a, and a conductive layer 124b. The core conductive layer 112a is disposed on the core layer 110, and the core conductive layer 112b is disposed under the core layer 110. The insulating layer 122a is disposed on the core conductive layer 112a, and the insulating layer 122b is disposed under the core conductive layer 112b. The conductive layer 124a is disposed on the insulating layer 122a, and the conductive layer 124b is disposed under the insulating layer 122b.

In some embodiments, the core layer 110, the insulating layer 122a and the insulating layer 122b may each include a dielectric material with a dielectric constant higher than 3.6 and a dissipation factor lower than 0.05, but the disclosure is not limited thereto. For example, the core layer 110, the insulating layer 122a and the insulating layer 122b may each include a film (e.g., epoxy resin impregnated fiberglass cloth), Ajinomoto build-up film material, bismaleimide-triazine resin (BT) resin or other suitable materials. In some embodiments, the core conductive layer 112a, the core conductive layer 112b, the conductive layer 124a and the conductive layer 124b may include copper, gold, silver, aluminum, tungsten or other suitable conductive materials, but the disclosure is not limited thereto.

In some embodiments, the core structure 102 may be formed by respectively laminating the insulating layer 122a with the conductive layer 124a and the insulating layer 122b with the conductive layer 124b on the two sides of the copper foil substrate. The copper foil substrate is composed of a core layer 110, a core conductive layer 112a and a core conductive layer 112b. In some embodiments, the conductive layer 124a and the conductive layer 124b may also be patterned through an electroplating process and an etching process.

In some embodiments, the core structure 102 may have an opening OP1 that penetrates the core structure 102. The side wall of the opening OP1 is, for example, composed of a conductive layer 124a, an insulating layer 122a, a core conductive layer 112a, a core layer 110, a core conductive layer 112b, an insulating layer 122b, and a conductive layer 124b. The first conductive via 152 and the insulating filling structure 142 may be disposed in the opening OP1. Specifically, the first conductive via 152 is disposed along the side wall of the opening OP1 and has a hollow structure, and the insulating filling structure 142 is located in the first conductive via 152. The opening OP1 does not penetrate the build-up structure 104, so that the build-up structure 104 may be disposed above the first conductive via 152 and the insulating filling structure 142.

n some embodiments, the core structure 102 also has an opening OP2 that penetrates the core structure 102. The side wall of the opening OP2 is, for example, composed of a conductive layer 124a, an insulating layer 122a, a core conductive layer 112a, a core layer 110, a core conductive layer 112b, an insulating layer 122b, and a conductive layer 124b. A conductive connector V may be disposed in the opening OP2 to electrically connect the conductive layers on the two sides of the core structure 102. For example, the conductive connector V may include a fourth conductive via 158 disposed along the side wall of the opening OP2 and an insulating filling structure 148 located in the fourth conductive via 158, but the disclosure is not limited thereto. In other embodiments, the fourth conductive via 158 may fill the opening OP2 without the insulating filling structure 148. The conductive connector V (or the opening OP2) does not penetrate the build-up structure 104, so that the build-up structure 104 may be disposed above the conductive connector V.

In some embodiments, the openings OP1 and OP2 may be formed, for example, through a stamping process, a drilling process, or other suitable processes, but the disclosure is not limited thereto.

In some embodiments, the build-up structure 104 may include a first insulating layer 132, a first conductive layer 134, a second insulating layer 136, and a second conductive layer 138 sequentially stacked above the core structure 102. In some embodiments, the first insulating layer 132 may be disposed on the conductive layer 124a of the core structure 102 and be in direct contact with the conductive layer 124a.

In some embodiments, the first insulating layer 132 and the second insulating layer 136 may each include a dielectric material with a dielectric constant higher than 3.5 and a dissipation factor lower than 0.05, but the disclosure is not limited thereto. For example, the first insulating layer 132 and the second insulating layer 136 may each include a film (e.g., epoxy resin impregnated fiberglass cloth), Ajinomoto build-up film material, bismaleimide-triazine resin (BT) resin or other suitable materials, but the disclosure is not limited thereto. The first conductive layer 134 and the second conductive layer 138 may each include copper, gold, silver, aluminum, tungsten or other suitable conductive materials, but the disclosure is not limited thereto.

In some embodiments, the build-up structure 104 may be formed by laminating the first insulating layer 132, the first conductive layer 134, the second insulating layer 136 and the second conductive layer 138 on the conductive layer 124a of the core structure 102. In some embodiments, the first conductive layer 134 and the second conductive layer 138 may also be patterned through an electroplating process and an etching process. FIG. 2 only schematically shows two insulating layers and two conductive layers as the build-up structure 104, but this is not intended to limit the disclosure. The number of insulating layers and conductive layers in the build-up structure 104 may be adjusted according to actual requirements.

In some embodiments, the first surface 100a of the substrate 100 may be composed of the top surface (e.g., the second conductive layer 138) of the build-up structure, and the second surface 100b of the substrate 100 may be composed of the bottom surface (e.g., the conductive layer 124b) of the core structure.

In some embodiments, the substrate 100 has a through hole TH1 that penetrates the build-up structure 104 and the core structure 102. The side wall of the through hole TH1 is, for example, composed of the side walls of the second conductive layer 138, the second insulating layer 136, the first insulating layer 132, and the insulating filling structure 142. The second conductive via 154 may be disposed in the through hole TH1. For example, the second conductive via 154 may be disposed along the side wall of the through hole TH1 and have a hollow structure, but the disclosure is not limited thereto. In other embodiments, the second conductive via 154 may fill the through hole TH1 and have a solid structure.

In some embodiments, the first conductive via 152 and the second conductive via 154 have the same axis, the first conductive via 152 surrounds the second conductive via 154, and the insulating filling structure 142 is located between the first conductive via 152 and a part of the second conductive via 154 and surrounds the second conductive via 154, and forms coaxial conductive vias (e.g., the first coaxial conductive via CV1 and the second coaxial conductive via CV2). In other words, the first coaxial conductive via CV1 and the second coaxial conductive via CV2 may each include a first conductive via 152, a second conductive via 154, and an insulating filling structure 142. The first conductive via 152 penetrates the core structure 102. The second conductive via 154 penetrates the core structure 102 and the build-up structure 104, and the first conductive via 152 surrounds the second conductive via 154. The insulating filling structure 142 is located between the first conductive via 152 and the second conductive via 154 to electrically isolate the first conductive via 152 from the second conductive via 154. The first insulating layer 132 and the second insulating layer 136 may electrically isolate the second conductive via 154 from the ground via GV (or the first conductive layer 134).

In an embodiment in which the second conductive via 154 has a hollow structure, the coaxial conductive vias (e.g., the first coaxial conductive via CV1 and the second coaxial conductive via CV2) may also include an insulating filling structure 144 located in the second conductive via 154. However, the disclosure is not limited thereto. In the embodiment in which the second conductive via 154 is a solid structure, the coaxial conductive vias (e.g., the first coaxial conductive via CV1 and the second coaxial conductive via CV2) do not include the insulating fill structure 144.

In some embodiments, the substrate 100 further has a through hole TH2 that penetrates the build-up structure 104 and the insulating filling structure 142. The side wall of the through hole TH2 is, for example, composed of the second conductive layer 138, the second insulating layer 136, the first conductive layer 134, the first insulating layer 132, the conductive layer 124a, the insulating layer 122a, the core layer 110, the core conductive layer 112b, the insulating layer 122b, and the conductive layer 124b. The ground via GV may be disposed in the through hole TH2, that is to say, the ground via GV may penetrate the build-up structure 104 and the core structure 102. For example, the ground via GV may include a third conductive via 156 disposed along the side wall of the through hole TH2 and an insulating filling structure 146 located in the third conductive via 156, but the disclosure is not limited thereto. In other embodiments, the third conductive via 156 may fill the through hole TH2 without the insulating filling structure 146.

In some embodiments, the through hole TH1 and the through hole TH2 may be formed through mechanical drilling, laser drilling, or other suitable processes. In some embodiments, the material of the insulating filling structures 142, 144, 146 and 148 is, for example, resin, which may be regarded as a plugging agent, or a dielectric material with a dielectric constant higher than 3.6 and a dissipation factor lower than 0.05, but the disclosure is not limited thereto.

In some embodiments, the first conductive via 152 may be electrically connected to the ground via GV. For example, the first conductive via 152 may be electrically connected to the ground via GV through the core conductive layer 112a, the core conductive layer 112b, the conductive layer 124a and/or the conductive layer 124b.

In some embodiments, the circuit board structure 10 further includes a first top circuit layer 160a, a second top circuit layer 162a, and a third top circuit layer 164a. The first top circuit layer 160a is disposed on the build-up structure 104 and is electrically connected to the second conductive via 154 of the first coaxial conductive via CV1. The second top circuit layer 162a is disposed on the build-up structure 104 and is electrically connected to the second conductive via 154 of the second coaxial conductive via CV2. The third top circuit layer 164a is disposed on the build-up structure 104 and is electrically connected to the ground via GV. The first top circuit layer 160a, the second top circuit layer 162a, and the third top circuit layer 164a are collectively referred to as top circuit layers.

In some embodiments, the circuit board structure 10 further includes a first bottom circuit layer (not shown), a second bottom circuit layer 162b, and a third bottom circuit layer 164b. The first bottom circuit layer is disposed under the core structure 102 and is electrically connected to the second conductive via 154 of the first coaxial conductive via CV1. The second bottom circuit layer 162b is disposed under the core structure 102 and is electrically connected to the second conductive via 154 of the second coaxial conductive via CV2. The third bottom circuit layer 164b is disposed under the core structure 102 and is electrically connected to the ground via GV. The first bottom circuit layer 160b, the second bottom circuit layer and the third bottom circuit layer 164b are collectively referred to as bottom circuit layers.

In some embodiments, the first bottom circuit layer, the second conductive via 154 of the first coaxial conductive via CV1 and the first top circuit layer 160a may form a first signal transmission path. The second bottom circuit layer 162b, the second conductive via 154 of the second coaxial conductive via CV2, and the second top circuit layer 162a may form a second signal transmission path. The third bottom circuit layer 164b, the ground via GV, the first conductive via 152 of the first coaxial conductive via CV1 and the second coaxial conductive via CV2, and the third top circuit layer 164a may form a ground path. In this way, the first signal transmission path and the second signal transmission path may be surrounded by the ground path. A high-frequency and high-speed signal may pass through the first signal transmission path and the second signal transmission path, and generate a return signal through the ground path to form a good high-frequency and high-speed loop.

The first coaxial conductive via CV1 and the second coaxial conductive via CV2 have low impedance. Specifically, the impedance of the first coaxial conductive via CV1 and the impedance of the second coaxial conductive via CV2 are less than 50 ohms respectively. For example, the impedance may be between 40 ohms and 50 ohms, between 40 ohms and 45 ohms, below 40 ohms, or other values, to reduce the size of the first coaxial conductive via CV1, the size of the second coaxial conductive via CV2, and the interval between the first coaxial conductive via CV1 and the second coaxial conductive via CV2. The impedance of the coaxial conductive via may be adjusted to achieve the target impedance by adjusting the dielectric constant of the insulating filling structure 142, the distance (i.e., the width of the insulating filling structure 142) between the second conductive via 154 and the first conductive via 152, etc.

In some embodiments, when the material of the insulating filling structure 142 is fixed, the ratio (i.e., D1/D2) of the inner diameter D1 (as shown in FIG. 3) of the first conductive via 152 to the outer diameter D2 (as shown in FIG. 3) of the second conductive via 154 is less than 4, for example, between 3 and 4, so that the impedance of the coaxial conductive via (e.g., the first coaxial conductive via CV1 and the second coaxial conductive via CV2) may be less than 50 ohms.

In some embodiments, when the ratio (i.e., D1/D2) of the inner diameter D1 of the first conductive via 152 to the outer diameter D2 of the second conductive via 154 is fixed, the material of the insulating filling structure 142 may be selected to have a relative dielectric constant Er that satisfies the following formula:

$$\frac{60}{\sqrt{{ε}_{r}}} ln ( \frac{D 1}{D 2} ) = Z ,$$

where Z is a predetermined target impedance (e.g., less than 50 ohms or other suitable values). In this way, the impedance of the coaxial conductive vias (e.g., the first coaxial conductive via CV1 and the second coaxial conductive via CV2) may be adjusted by adjusting the material of the insulating filling structure 142.

In some embodiments, as shown in FIG. 1, the distance D3 between the axis center of the first coaxial conductive via CV1 and the axis center of the second coaxial conductive via CV2 may be less than 1.3 mm, such as 1 mm or other values, to reduce the distance between the first coaxial conductive via CV1 and the second coaxial conductive via CV2, thereby improving the availability of circuit board space.

Referring to FIG. 4, FIG. 4 shows the results of simulated reflection loss at different operating frequencies with the impedance of the coaxial conductive via being 40 ohms. When the coaxial conductive via operates in the frequency range between 50 GHz and 68 GHz, its reflection loss parameter S11 is less than-15 dB, which has good signal integrity. When the coaxial conductive via operates in the frequency range below 50 GHz or above 68 GHz, its reflection loss parameter S11 is greater than-15 dB, causing signal transmission losses and affecting the quality of signal transmission. It may be seen that the first coaxial conductive via CV1 and the second coaxial conductive via CV2 have low impedance (e.g., the impedance is less than 50 ohms) and are configured to transfer a signal with a frequency in the range between 50 GHz and 68 GHz, thereby enabling a reduction in the size and interval of the first coaxial conductive via CV1 and the second coaxial conductive via CV2 while simultaneously maintaining signal integrity.

In some embodiments, as shown in FIG. 1, the axis centers of the ground vias GV may surround the axis center of the first coaxial conductive via CV1 or the axis center of the second coaxial conductive via CV2. For example, some ground vias GV may be evenly disposed on a circle C1 with the axis center of the first coaxial conductive via CV1 as the center and a radius of R1, and the distance between the center of the ground vias GV and the axis center of the first coaxial conductive via CV1 is approximately the radius R1. Some ground vias GV may be evenly disposed on a circle C2 with the axis center of the second coaxial conductive via CV2 as the center and a radius of R2, and the distance between the center of the ground vias GV and the axis center of the second coaxial conductive via CV2 is approximately the radius R2. In some embodiments, the radius R1 and the radius R2 may be substantially the same, but the disclosure is not limited thereto. In other embodiments, the radius R1 may be different from the radius R2. The radius R1 and the radius R2 may be reduced as much as possible within the processing capability, for example, between 350 μm and 700 μm. It should be understood that the circle C1 and the circle C2 in FIG. 1 are drawn for convenience of explanation and do not exist in the circuit board structure 10.

In some embodiments, the number of ground vias GV on the circle C1 and the circle C2 may be reduced as much as possible without affecting signal integrity and signal quality to save space. For example, some ground vias GV (e.g., the ground vias GV1 and GV2) may be located at the intersection of the circles C1 and C2, so that the ground vias GV1 and GV2 may simultaneously serve as ground barriers for the second conductive via 154 of the first coaxial conductive via CV1 and the second conductive via 154 of the second coaxial conductive via CV2, so that the space may be effectively use.

In some embodiments, a shortest distance between centers of the ground vias GV and the axis center of the first coaxial conductive via CV1 is a first distance (e.g., the radius R1). A shortest distance between the centers of the ground vias GV and the axis center of the second coaxial conductive via CV2 is a second distance (e.g., the radius R2). A sum (e.g., R1+R2) of the first distance and the second distance is greater than a distance D3 between the axis center of the first coaxial conductive via CV1 and the axis center of the second coaxial conductive via CV2. That is, no ground via GV is disposed on the straight line connecting the axis centers of the adjacent first coaxial conductive via (CV1) and the second coaxial conductive via (CV2).

In some embodiments, the first top circuit layer 160a may include a pad portion 160a1, a first circuit portion 160a2, and a second circuit portion 160a3. The pad portion 160al is disposed on the second conductive via 154 of the first coaxial conductive via CV1. The first circuit portion 160a2 is disposed on the second conductive layer 138 of the build-up structure 104. The second circuit portion 160a3 is disposed on the second conductive layer 138 of the build-up structure 104 and is connected between the pad portion 160al and the first circuit portion 160a2.

In some embodiments, the second circuit portion 160a3 may be located within the circle C1. The length of the second circuit portion 160a3 may be adjusted according to the transmission frequency requirements. For example, the length L of the second circuit portion 160a3 may be between 0.3 mm and 0.7 mm, so that the center of the transmission frequency falls at approximately 62±2 GHz.

In some embodiments, the width W2 of the second circuit portion 160a3 may be less than the width W1 of the first circuit portion 160a2 to compensate for the portion of the second conductive via 154 of the first coaxial conductive via CV1 that is not surrounded by the ground vias GV, so as to achieve impedance matching.

Similarly, the second top circuit layer 162a may also include a pad portion (not labeled), a first circuit portion (not labeled), and a second circuit portion (not labeled) similar to that of the first top circuit layer 160a, and have a similar configuration to the first top circuit layer 160a, and their descriptions are not repeated herein.

In some embodiments, the circuit board structure 10 further includes multiple ground vias GV′ disposed on two sides of the first circuit portion 160a2 of the first top circuit layer 160a and the first circuit portion of the second top circuit layer 162a. In some embodiments, the ground via GV′ may, for example, extend through the second conductive layer 138 and the second insulating layer 136.

In some embodiments, the circuit board structure 10 further includes passivation layers 170a and 170b respectively disposed on the top circuit layer and the bottom circuit layer to protect the internal structure. In some embodiments, the passivation layers 170a and 170b may have openings that expose a part of the top circuit layer and a part of the bottom circuit layer to serve as an interface for electrical connection with the outside world. For example, an antenna structure (not shown) may be disposed on the first surface 100a of the substrate 100 and connected to a part of the top circuit layer through the opening of the passivation layer 170a, and a chip may be disposed under the second surface 100b of the substrate 100 and connected to a part of the bottom circuit layer through the opening of the passivation layer 170b. That is, the antenna structure and the chip may be respectively disposed on opposite sides of the circuit board structure 10. This may reduce noise, facilitate heat dissipation of the chip, and reduce the size of the circuit board structure 10.

In some embodiments, the first coaxial conductive via CV1 (and the first top circuit layer 160a) may be configured to transfer a signal from the antenna structure to the chip, functioning as a receiver. The second coaxial conductive via CV2 (and the second top circuit layer 162a) may be configured to transfer a signal from the chip to the antenna structure, functioning as a transmitter. However, the disclosure is not limited thereto. The first coaxial conductive via CV1 and the second coaxial conductive via CV2 may selectively transfer the received or transmitted signal according to actual requirements.

To sum up, the circuit board structure of the disclosure includes coaxial conductive vias. The coaxial conductive vias have low impedance and are configured to transfer a signal with a frequency in a range between 50 GHz and 68 GHz, thereby increasing the space utilization of the circuit board, while taking into account the integrity of the transferred signal.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A circuit board structure, comprising:
a substrate, having a first surface and a second surface opposite to the first surface;
a first coaxial conductive via and a second coaxial conductive via, disposed in the substrate, wherein an impedance of the first coaxial conductive via and an impedance of the second coaxial conductive via are less than 50 ohms respectively; and
a plurality of ground vias, surrounding the first coaxial conductive via and the second coaxial conductive via,
wherein the first coaxial conductive via and the second coaxial conductive via are configured to transfer a signal with a frequency in a range between 50 GHz and 68 GHz.

2. The circuit board structure according to claim 1, wherein the substrate comprises
a core structure; and
a build-up structure, disposed on the core structure, wherein the build-up structure is close to the first surface of the substrate relative to the core structure.

3. The circuit board structure according to claim 2, wherein the first coaxial conductive via and the second coaxial conductive via each comprise:
a first conductive via, penetrating the core structure;
a second conductive via, penetrating the core structure and the build-up structure, wherein the first conductive via surrounds the second conductive via, and the first conductive via and the second conductive via have the same axis center; and
an insulating filling structure, located between the first conductive via and the second conductive via.

4. The circuit board structure according to claim 3, wherein a ratio of an inner diameter of the first conductive via to an outer diameter of the second conductive via is less than 4.

5. The circuit board structure according to claim 3, wherein the first conductive via is electrically connected to the ground vias.

6. The circuit board structure according to claim 2, wherein the ground vias penetrate the build-up structure and the core structure.

7. The circuit board structure according to claim 1, wherein a distance between an axis center of the first coaxial conductive via and an axis center of the second coaxial conductive via is less than 1.3 mm.

8. The circuit board structure according to claim 3, further comprising:
a first top circuit layer, disposed on the build-up structure and electrically connected to the second conductive via of the first coaxial conductive via.

9. The circuit board structure according to claim 8, wherein the first top circuit layer comprises:
a pad portion, disposed on the second conductive via of the first coaxial conductive via;
a first circuit portion, disposed on the build-up structure; and
a second circuit portion, disposed on the build-up structure and connected between the pad portion and the first circuit portion, wherein a width of the second circuit portion is less than a width of the first circuit portion.

10. The circuit board structure according to claim 1, wherein a shortest distance between centers of the ground vias and an axis center of the first coaxial conductive via is a first distance a shortest distance between the centers of the ground vias and an axis center of the second coaxial conductive via is a second distance, a sum of the first distance and the second distance is greater than a distance between the axis center of the first coaxial conductive via and the axis center of the second coaxial conductive via.
